(19) United States
(12) Patent Application Publication
(10) Pub. No.: US 2025/0253238 A1
(43) Pub. Date: Aug. 7, 2025

(54) BACKSIDE TO FRONTSIDE CONNECTION BETWEEN DIFFERENT METAL TRACKS

(71) Applicant: INTERNATIONAL BUSINESS MACHINES CORPORATION, ARMONK, NY (US)

(72) Inventors: Albert M. Chu, Nashua, NH (US); Ruilong Xie, Niskayuna, NY (US); Lawrence A. Clevenger, Saratoga Springs, NY (US); Brent A. Anderson, Jericho, VT (US); Nicholas Anthony Lanzillo, Wynantskill, NY (US); David Wolpert, Poughkeepsie, NY (US); James P Mazza, Saratoga Springs, NY (US)

(21) Appl. No.: 18/434,903

(22) Filed: Feb. 7, 2024

(51) Int. Cl. H01L 23/528; H01L 21/8234; H01L 23/522; H01L 27/088; H01L 29/06; H01L 29/417; H01L 29/423; H01L 29/66; H01L 29/775; H01L 29/786

(52) U.S. Cl. CPC H01L 23/5283; H01L 23/5226; H10D 30/014; H10D 30/43; H10D 30/6729; H10D 30/6735; H10D 30/6757; H10D 62/121; H10D 64/017; H10D 64/021; H10D 84/0149; H10D 84/038; H10D 84/83

(57) ABSTRACT

Embodiments of present invention provide a semiconductor structure. The semiconductor structure includes a deep trench via in a double diffusion region between a first dummy metal gate and a second dummy metal gate; a frontside metal wire conductively connected to a top surface of the deep trench via through a frontside via; and a backside metal wire conductively connected to a bottom surface of the deep trench via through a backside via and a backside contact, where the frontside metal wire and the backside metal wire are not vertically aligned but parallel to each other, and directions of the frontside and backside metal wires are orthogonal to a length direction of the deep trench via. A method of forming the same is also provided.

### BACKGROUND

The present application relates to manufacturing of semiconductor integrated circuits. More particularly, it relates to method of forming backside to frontside connection between different metal tracks, and the structure formed thereby.

As semiconductor industry moves towards smaller node, field-effect-transistors (FETs) are aggressively scaled to fit into reduced footprint or real estate, which is often dictated by the node size, with increased device density. In addition, backside power distribution network (BSPDN) is introduced as a mean to further enhance the device density.

With a semiconductor chip with both frontside metal tracks, of a frontside back-end-of-line (BEOL) structure and backside metal tracks of a backside BEOL (BBEOL) structure, there is often the need for communication to take place among different metal tracks at the frontside and at the backside. For example, a metal level 1 (M1) at the frontside may need to talk to a M1 at the backside. When the M1 at the frontside is vertically aligned with the M1 at the backside, such communication may be enabled by a deep vertical via formed between the two metal levels. However, metal levels at the frontside and the backside are not always aligned in reality such as be misaligned for various reasons. In this case, a vertical via may not be able to connect the frontside metal level with the backside metal level.

### SUMMARY

Embodiments of present invention provide a semiconductor structure. The semiconductor structure includes a deep trench via in a double diffusion region; a frontside metal wire conductively connected to a top surface of the deep trench via; and a backside metal wire conductively connected to a bottom surface of the deep trench via, where the frontside metal wire and the backside metal wire are parallel to each other and orthogonal to the deep trench via.

According to one embodiment, the semiconductor structure further includes a first dummy metal gate and a second dummy metal gate, where the double diffusion region is between the first dummy metal gate and the second dummy metal gate and the top surface of the deep trench via is at or above a top surface of the first dummy metal gate and the second dummy metal gate.

According to another embodiment, the semiconductor structure further includes a first set of nanosheets surrounded by the first dummy metal gate and a first set of inner spacers next to the first set of nanosheets, and a second set of nanosheets surrounded by the second dummy metal gate and a second set of inner spacers next to the second set of nanosheets, where the deep trench via is between the first set of inner spacers and the second set of inner spacers.

According to yet another embodiment, the semiconductor structure further includes a first sidewall spacer at a sidewall of the first dummy metal gate and a second sidewall spacer at a sidewall of the second dummy metal gate, where the deep trench via is insulated from the first and the second dummy metal gate by the first and the second sidewall spacer and from the first and the second set of nanosheets by the first and the second set of inner spacers.

According to one embodiment, the semiconductor structure further includes a first nanosheet transistor having a first source/drain (S/D) region adjacent to the first dummy metal gate, a second nanosheet transistor having a second S/D region adjacent to the second dummy metal gate, a backside contact contacting the deep trench via from underneath thereof, and a backside S/D contact contacting the first S/D region from underneath thereof, where a height of the backside contact is lower than a height of the backside S/D contact.

According to another embodiment, the semiconductor structure further includes a frontside via, a backside via, and a backside contact, where the frontside metal wire is conductively connected to the top surface of the deep trench via through the frontside via, and the backside metal wire is conductively connected to the bottom surface of the deep trench via through the backside via and the backside contact.

In one embodiment, the frontside metal wire is not vertically aligned with the backside metal wire and a horizontal distance between the frontside and backside metal wires is less than a length of the deep trench via.

Embodiments of present invention provide a method of forming a semiconductor structure. The method includes forming a placeholder in a substrate; forming a first dummy metal gate and a second dummy metal gate on the substrate, the first dummy metal gate surrounding a first set of nanosheets at a first side of the placeholder and the second dummy metal gate surrounding a second set of nanosheets at a second side of the placeholder; forming a deep trench via between the first dummy metal gate and the second dummy metal gate, the deep trench via in contact with the placeholder in the substrate; forming a frontside metal wire conductively connected to a top surface of the deep trench via; replacing the placeholder with a backside contact contacting a bottom surface of the deep trench via; and forming a backside metal wire conductively connected to the bottom surface of the deep trench via through the backside contact.

According to one embodiment, the method further includes forming a frontside via directly contacting the top surface of the deep trench via, where the frontside metal wire directly contacts the frontside via.

According to another embodiment, the method further includes forming a backside via directly contacting the backside contact, where the backside metal wire directly contacts the backside via.

According to yet another embodiment, the method further includes forming a first set of inner spacers next to an end of the first set of nanosheets facing the deep trench via and a second set of inner spacers next to an end of the second set of nanosheets facing the deep trench via such that the deep trench via is between the first set of inner spacers and the second set of inner spacers.

In one embodiment, forming the deep trench via includes creating a deep trench via opening in a dielectric layer between the first dummy metal gate and the second dummy metal gate; and filling the deep trench via opening with a conductive material to form the deep trench via, wherein a top surface of the deep trench via is at a level at or above a top surface of the first and the second dummy metal gate.

In another embodiment, forming the frontside metal wire includes forming the frontside metal wire in a first direction orthogonal to the deep trench via; and forming the backside metal wire includes forming the backside metal wire in a second direction orthogonal to the deep trench via and parallel to the first direction, where the backside metal wire is not vertically aligned with the frontside metal wire.

In yet another embodiment, replacing the placeholder with the backside contact includes selectively removing the placeholder from a backside of the substrate to creating an opening exposing the bottom surface of the deep trench via and filling the opening with a conductive material to form the backside contact.

In one embodiment, forming the first and the second dummy metal gate includes forming a set of metal gates that includes a first metal gate of a first transistor, a second metal gate of a second transistor, and the first and the second dummy metal gate; and replacing the placeholder with the backside contact further includes forming a backside source/drain (S/D) contact underneath a first S/D region of the first transistor, where a height of the backside contact is lower than a height of the backside S/D contact.

### BRIEF DESCRIPTION OF THE DRAWINGS

The present invention will be understood and appreciated more fully from the following detailed description of embodiments of present invention, taken in conjunction with accompanying drawings of which:

FIGS. 1A and 1B to FIGS. 12A and 12B are demonstrative illustrations of cross-sectional views and FIG. 1C to FIG. 12C are simplified top views of a semiconductor structure at various steps of manufacturing thereof according to embodiments of present invention; and

FIG. 13 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

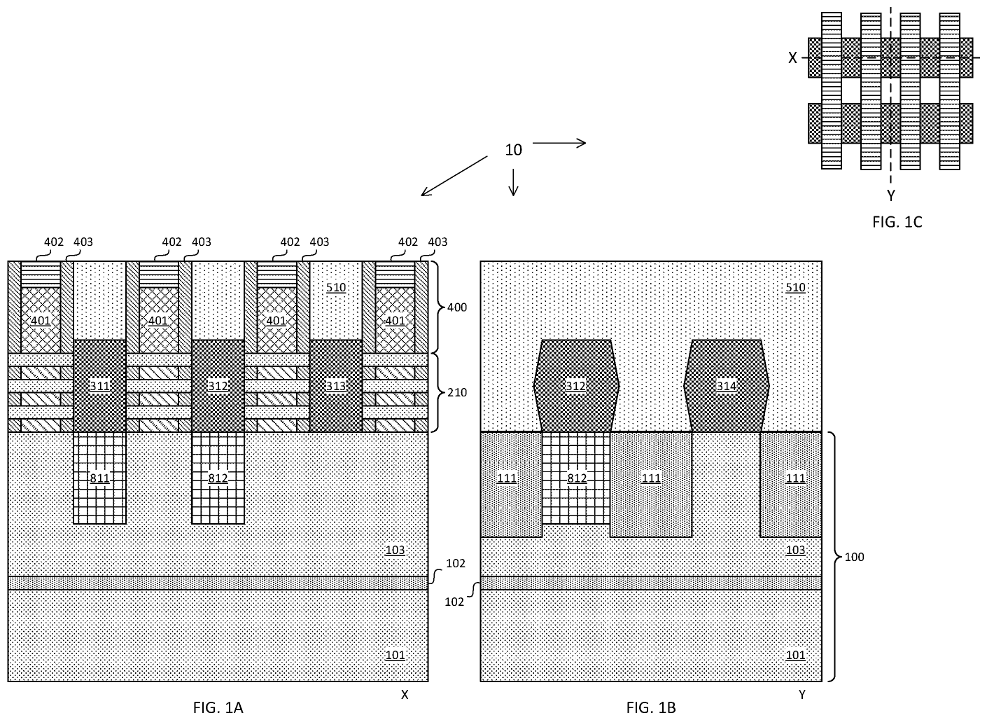

FIGS. 1A and 1B are demonstrative illustrations of different cross-sectional views and FIG. 1C is a simplified top view of a semiconductor structure in a step of manufacturing thereof according to one embodiment of present invention. More specifically, FIG. 1A illustrates a cross-sectional view of the semiconductor structure along a dashed line X as illustrated in FIG. 1C. In other words, the cross-sectional view in FIG. 1A is made across the gate in a direction along the length of the gate. FIG. 1B illustrates a cross-sectional view of the semiconductor structure along a dashed line Y as illustrated in FIG. 1C. In other words, the cross-sectional view in FIG. 1B is made across the S/D region in a direction along the width of the gate. As its purpose is to show locations of the cross-sections illustrated in FIGS. 1A and 1B, FIG. 1C may selectively illustrate key elements such as, for example, nanosheets, gates, S/D regions, and elements that are formed or yet to be formed and whose views may be covered or exposed. Other elements such as dielectric cap layer, sidewall spacers, etc. may not necessarily be illustrated in order not to overcrowd FIG. 1C, and to the extent that their omission from FIG. 1C does not hinder the description of embodiments of present invention, which are mainly provided hereinafter with reference to FIGS. 1A and 1B.

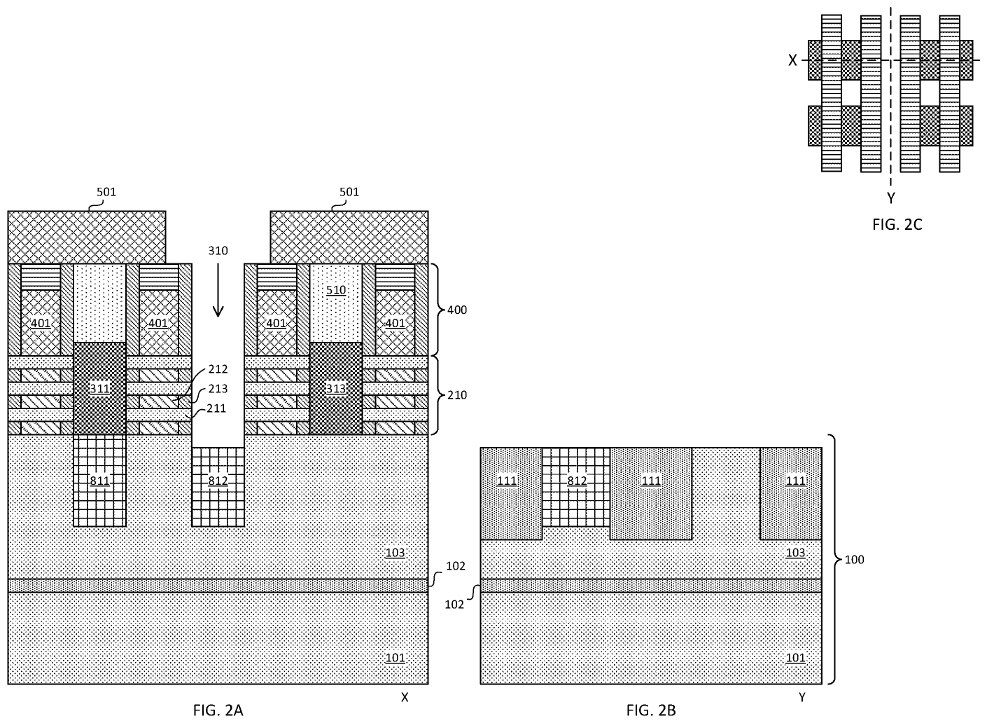

Likewise, FIGS. 2A and 2B to FIGS. 12A and 12B are demonstrative cross-sectional views and FIG. 2C to FIG. 12C are simplified top views of the semiconductor structure, at different manufacturing steps, illustrated in manners similar to FIGS. 1A, 1B, and 1C respectively.

Referring back to FIGS. 1A, 1B, and 1C, embodiments of present invention provide forming a semiconductor structure 10 that is demonstratively illustrated to include multiple sets of nanosheets 210 on top of a semiconductor substrate 100. The semiconductor substrate 100 may include a bulky silicon (Si) substrate 101, an etch-stop layer 102 on top of the Si substrate 101, and a Si layer 103 on top of the etch-stop layer 102. The etch-stop layer 102 may be a layer of dielectric material such as silicon-oxide (SiO₂) or silicon-nitride (SiN), or a layer of silicon-germanium (SiGe) having a material composition that is different from the Si substrate 101 so as to enabling a selective etch process based on difference in material etch selectivity. One or more placeholders may be formed in the Si layer 103 such as a first placeholder 811 and a second placeholder 812. The first and the second placeholder 811 and 812 may be made of a material different from the Si layer 103 such that they may be selectively removed later in a selective etch process. The Si layer 103 may also be formed to include one or more shallow-trench-isolations (STIs) 111.

The semiconductor structure 10 may also include multiple sacrificial gate structures 400 on top of, and covering, the multiple sets of nanosheets 210. Each of the multiple sacrificial gate structures 400 may include a sacrificial gate 401 covered by a gate mask 402 on top thereof. Sidewall spacers 403 may be formed at sidewalls of the sacrificial gate 401. The semiconductor structure 10 may also include multiple source/drain (S/D) regions such as a first S/D region 311, a second S/D region 312, and a third S/D region 313 that are formed at the end of the multiple sets of nanosheets 210 and covered by a dielectric layer 510. The dielectric layer 510 fills spaces between the multiple sacrificial gate structures 400.

FIGS. 2A and 2B are demonstrative illustrations of different cross-sectional views and FIG. 2C is a simplified top view of a semiconductor structure in a step of manufacturing thereof, according to one embodiment of present invention. More particularly, following the step illustrated in FIGS. 1A, 1B, and 1C, embodiments of present invention provide forming a double diffusion break between two sacrificial gate structures 400. For example, embodiments of present invention provide forming a hard mask 501 on top of the multiple sacrificial gate structures 400 and the dielectric layer 510. The hard mask 501 may be, for example, an organic-planarization-layer (OPL) and may be patterned to have an opening exposing a portion of the dielectric layer 510 that is above the second S/D region 312. Next, the exposed portion of the dielectric layer 510 is removed, for example, through a selective etch process such as a reactive-ion-etch (RIE) process, thereby exposing the second S/D region 312 underneath thereof. Subsequently, the exposed second S/D region 312 is removed through a selective etch process as well. The removal of the second S/D region 312 may cause a portion of the second placeholder 812 underneath thereof be removed, resulting the second placeholder 812 to have a height that is lower than a height of the first placeholder 811 underneath the first S/D region 311.

Each of the multiple set of nanosheets 210 may include one or more nanosheets 211. The removal of the second S/D region 312 creates an opening 310 that exposes an end surface of the one or more nanosheets 211 of the two sets of nanosheets 210 adjacent to the second S/D region 312. The opening 310 also exposes the sidewall spacers 213 between the one or more nanosheets 211. The one or more nanosheets 211 may be separated from each other by one or more sacrificial sheets 212 there-in-between and behind the sidewall spacers 213. The sidewall spacers 213 may be known as inner spacers as well and may be formed through an indentation process in a previous step.

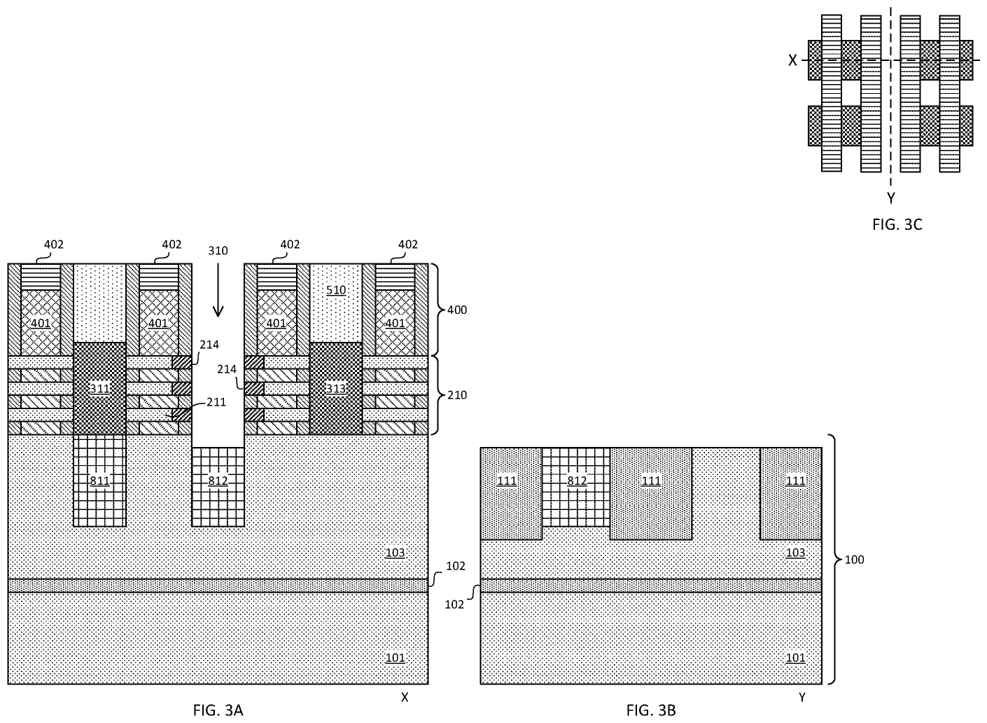

FIGS. 3A and 3B are demonstrative illustrations of different cross-sectional views and FIG. 3C is a simplified top view of a semiconductor structure in a step of manufacturing thereof, according to one embodiment of present invention. More particularly, following the step illustrated in FIGS. 2A, 2B, and 2C, embodiments of present invention provide forming one or more inner spacers 214 at the end of the one or more nanosheets 211 exposed by the opening 310. For example, in forming the one or more inner spacers 214, the one or more nanosheets 211 may first be recessed at their respective ends to create one or more indentations. The one or more indentations may subsequently be filled with, through for example a deposition process, a dielectric material to form the inner spacers 214. The inner spacers 214 are adjacent to and face a deep trench via, to be formed later in the opening 310, and insulate the one or more nanosheets 211 from the deep trench via.

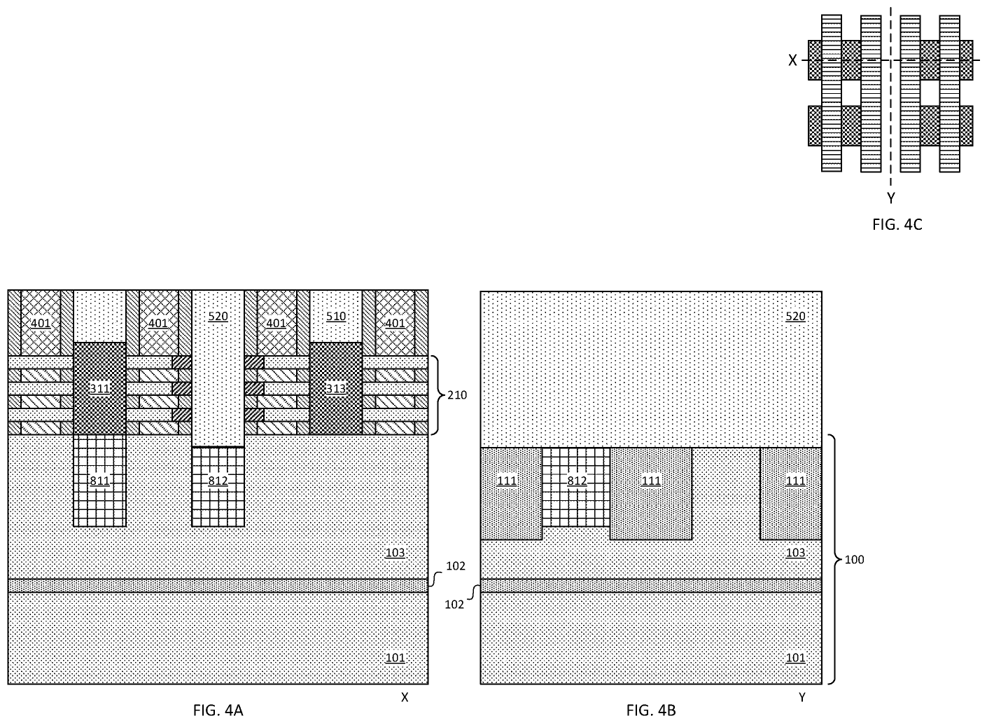

FIGS. 4A and 4B are demonstrative illustrations of different cross-sectional views and FIG. 4C is a simplified top view of a semiconductor structure in a step of manufacturing thereof, according to one embodiment of present invention. More particularly, following the step illustrated in FIGS. 3A, 3B, and 3C, embodiments of present invention provide filling the opening 310 with a dielectric material, such as SiO₂, SiN, SiBCN, SiOCN, SiOC or SiC to name a few, to form a double diffusion break 520. Next, a planarization process, such as a chemical-mechanical-polishing (CMP) process, may be applied to planarize a top surface of the double diffusion break 520. The planarization process may also remove the gate masks 402 thereby exposing the sacrificial gates 401 underneath thereof.

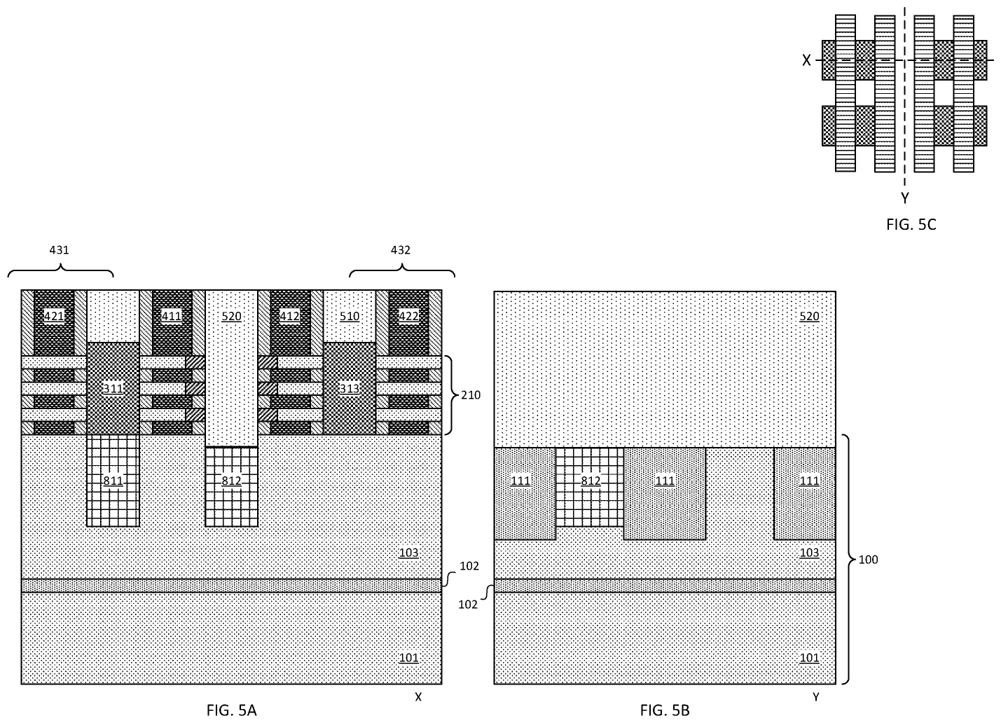

FIGS. 5A and 5B are demonstrative illustrations of different cross-sectional views and FIG. 5C is a simplified top view of a semiconductor structure in a step of manufacturing thereof, according to one embodiment of present invention. More particularly, following the step illustrated in FIGS. 4A, 4B, and 4C, embodiments of present invention provide forming metal gates of one or more nanosheet transistors in a replacement-metal-gate (RMG) process. For example, embodiments of present invention provide selectively removing the sacrificial gates 401 between the sidewall spacers 403 and selectively removing the sacrificial sheets 212 that separate the one or more nanosheets 211, thereby exposing a central portion of the one or more nanosheets 211 of the multiple sets of nanosheets 210. Next, one or more metal gates may be formed by first depositing or forming a gate dielectric layer covering the exposed portions of the one or more nanosheets 211; depositing or forming one or more work-function metal layers on top of the gate dielectric layer; and depositing or forming one or more gate metals on top of the work-function metal layers. The gate metals may include, for example, tungsten (W), cobalt (Co), ruthenium (Ru), copper (Cu), aluminum (AI), or other suitable materials.

The one or more metal gates may include, for example, a first dummy metal gate 411 and a second dummy metal gate 412, both of which may be adjacent to the double diffusion break 520. As is demonstratively illustrated in FIG. 5A, the first dummy metal gate 411 surrounds a set of nanosheets 210 that is to the left of the double diffusion break 520, with a first set of inner spacers 214 next to an end or end surface (e.g., the right-side end) of the set of nanosheets 210. Similarly, the second dummy metal gate 412 surrounds a set of nanosheets 210 that is to the right of the double diffusion break 520, with a second set of inner spacers 214 next to an end or end surface (e.g., the left-side end) of the set of nanosheets 210. The dummy metal gates 411 and 412 are insulated from the double diffusion break 520 by the sidewall spacers 403 and the sidewall spacers 213 between the nanosheets 211, while the one or more nanosheets 211 are insulated from the double diffusion break 520 by the inner spacers 214. Additionally, the one or more metal gates may include a first metal gate 421 of a first transistor 431 and a second metal gate 422 of a second transistor 432.

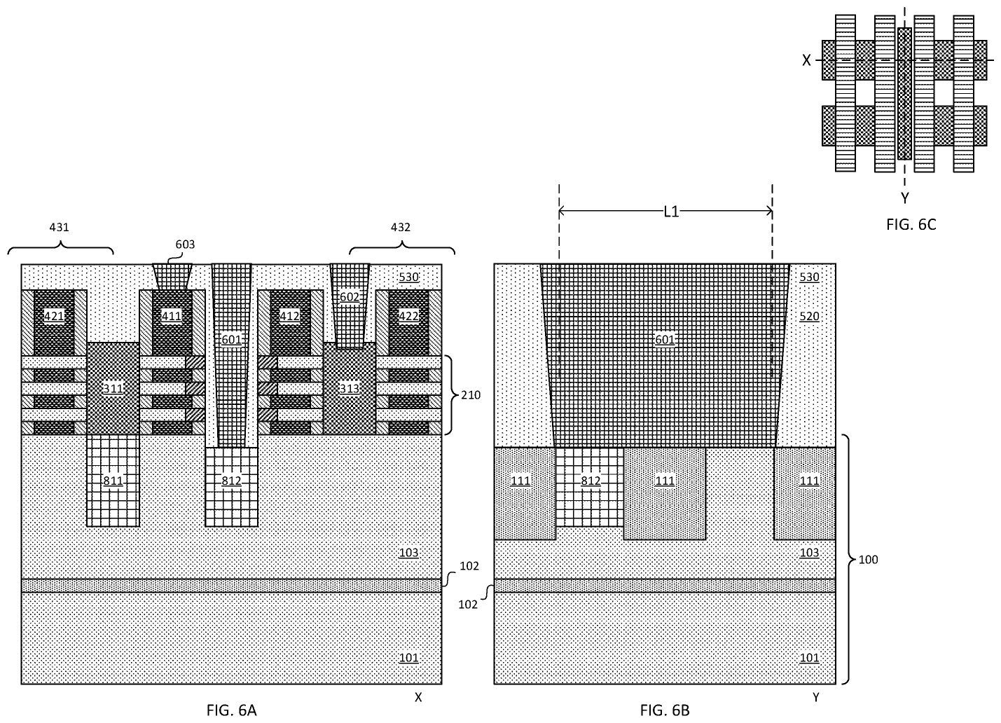

FIGS. 6A and 6B are demonstrative illustrations of different cross-sectional views and FIG. 6C is a simplified top view of a semiconductor structure in a step of manufacturing thereof, according to one embodiment of present invention. More particularly, following the step illustrated in FIGS. 5A, 5B, and 5C, embodiments of present invention provide depositing dielectric material on top of the first and second dummy metal gates 411 and 412 and the first and second metal gates 421 and 422 to form a dielectric layer 530, and subsequently forming one or more middle-of-line (MOL) local interconnects in the dielectric layer 510 and 530 and in the double diffusion break 520.

More particularly, embodiments of present invention provide forming a first MOL local interconnect, such as a deep trench via 601, in the double diffusion break 520. In doing so, embodiments of present invention provide creating a deep trench via opening in the dielectric layer 530, into and through the double diffusion break 520 until a top surface of the second placeholder 812 underneath the double diffusion break 520 is exposed. The deep trench via opening is then filled with a conductive material such as, for example, W, Co, Ru, Cu, Al, or other suitable materials, together with silicide liners and/or metal adhesion liners to form a deep trench via 601 which serves as a local interconnect. The fill of the deep trench via opening may be made through an atomic-layer-deposition (ALD) process, a chemical-vapor-deposition (CVD) process, and/or a physical-vapor-deposition (PVD) process. The deep trench via 601 may be in contact with the second placeholder 812 and have a top surface that is at or above a top surface of the first and the second dummy metal gates 411 and 412.

The deep trench via 601 may be formed inside the double diffusion break 520; be widthwise between the first and the second dummy metal gates 411 and 412; and have a length L1 in a direction parallel to the width of the dummy metal gates 411 and 412 or the first and the second metal gates 421 and 422, as is demonstratively illustrated in FIG. 6B. In addition to being possibly insulated by the double diffusion break 520, the deep trench via 601 may be insulated from the first and the second dummy metal gates 411 and 412 by the sidewall spacers 403 and the sidewall spacers 213 and insulated from the one or more nanosheets 211 of the two sets of nanosheets 210 adjacent to the double diffusion break 520 by the first and the second set of inner spacers 214.

Separately or concurrently with the forming of the deep trench via 601, one or more frontside source/drain (S/D) contact and/or gate contact may be formed in the dielectric layers 510 and 530. For example, a frontside S/D contact 602 may be formed through the dielectric layers 510 and 530 to be in contact with a top surface of the third S/D region 313, and a frontside gate contact 603 may be formed through the dielectric layer 530 to be in contact with a top surface of the first dummy metal gate 411. The frontside S/D contact 602 and the frontside gate contact 603 may be made of a conductive material such as W, Co, Ru, Cu, Al and/or other suitable conductive material, with a silicide liner and/or metal adhesion liner possibly formed between the conductive material and the dielectric layers 510 and 530.

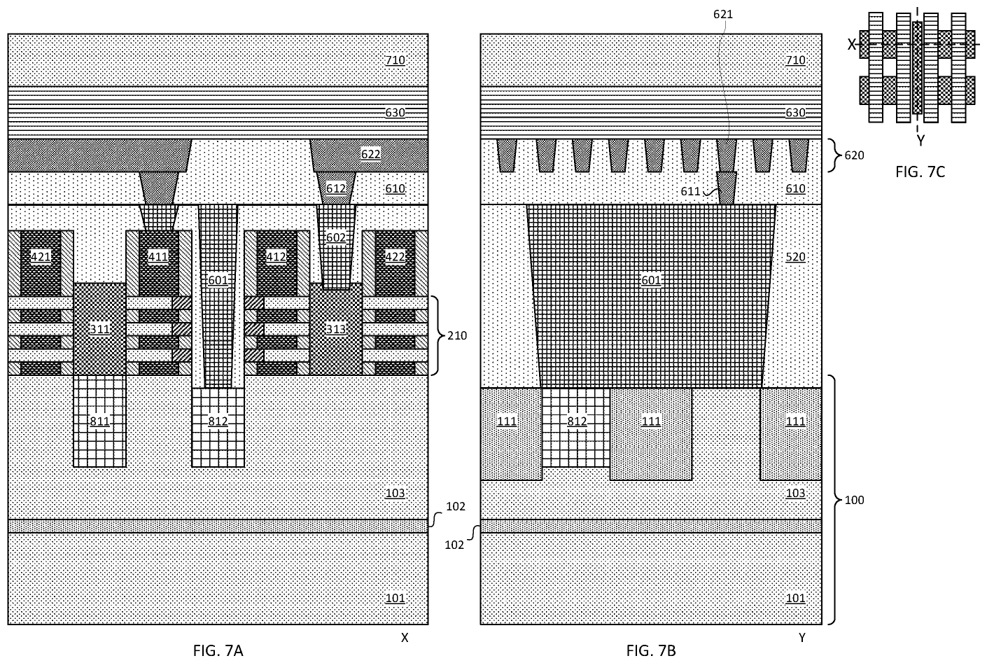

FIGS. 7A and 7B are demonstrative illustrations of different cross-sectional views and FIG. 7C is a simplified top view of a semiconductor structure in a step of manufacturing thereof, according to one embodiment of present invention. More particularly, following the step illustrated in FIGS. 6A, 6B, and 6C, embodiments of present invention provide forming additional dielectric layer such as a dielectric layer 610 on top of the semiconductor structure 10, in particular on top of the dielectric layer 530, the deep trench via 601, the frontside S/D contact 602, and the frontside gate contact 603, and forming one or more frontside vias such as a first frontside via 611 in direct contact with the top surface of the deep trench via 601 of local interconnect, and a second frontside via 612 in direct contact with the frontside S/D contact 602.

Embodiments of present invention further provide forming a frontside metal level such as a frontside metal level 620 on top of the dielectric layer 610. The frontside metal level 620 may include a plurality of metal tracks such as a plurality of metal wires, including a first frontside metal wire 621 and a second frontside metal wire 622, orientated in a first direction perpendicular or orthogonal to the length direction of the deep trench via 601. The first frontside metal wire 621 may be conductively connected to a top surface of the deep trench via 601 through the first frontside via 611.

Embodiments of present invention provide forming additional metal levels or back-end-of-line (BEOL) structure 630 on top of the frontside metal level 620. Next, a handling wafer 710 may be attached, such as through bonding, to the BEOL structure 630 such that the semiconductor structure 10 may be flipped upside-down for further processing from a backside of the semiconductor substrate 100.

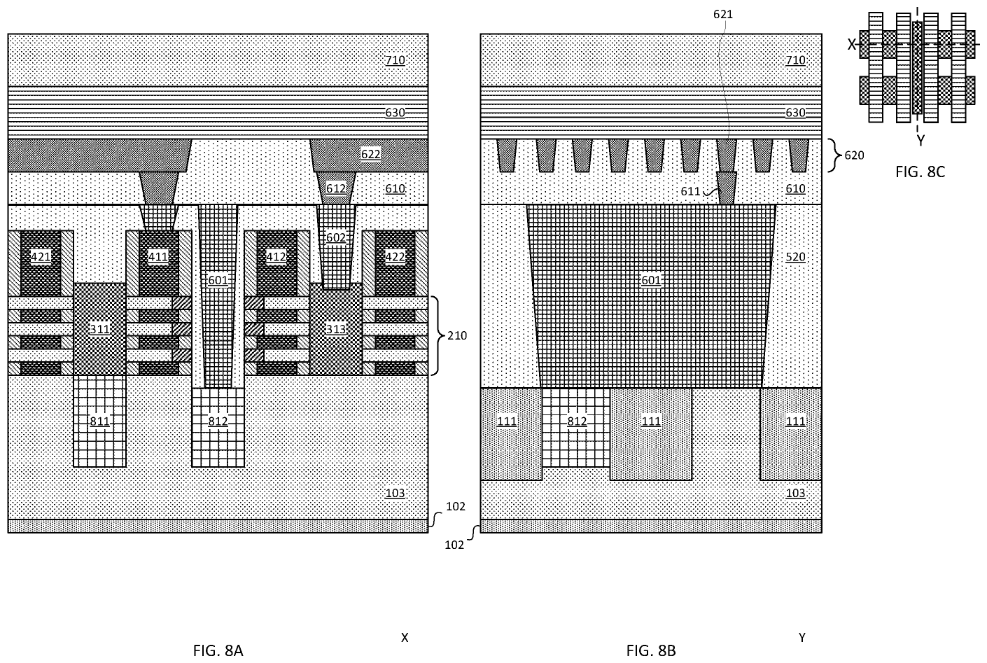

FIGS. 8A and 8B are demonstrative illustrations of different cross-sectional views and FIG. 8C is a simplified top view of a semiconductor structure in a step of manufacturing thereof, according to one embodiment of present invention. More particularly, following the step illustrated in FIGS. 7A, 7B, and 7C, embodiments of present invention provide selectively removing the bulky Si substrate 101 from the backside of the semiconductor substrate 100. The removal may be made through a grinding process, a wet or dry etch process, and/or a CMP process until the etch-stop layer 102 is exposed.

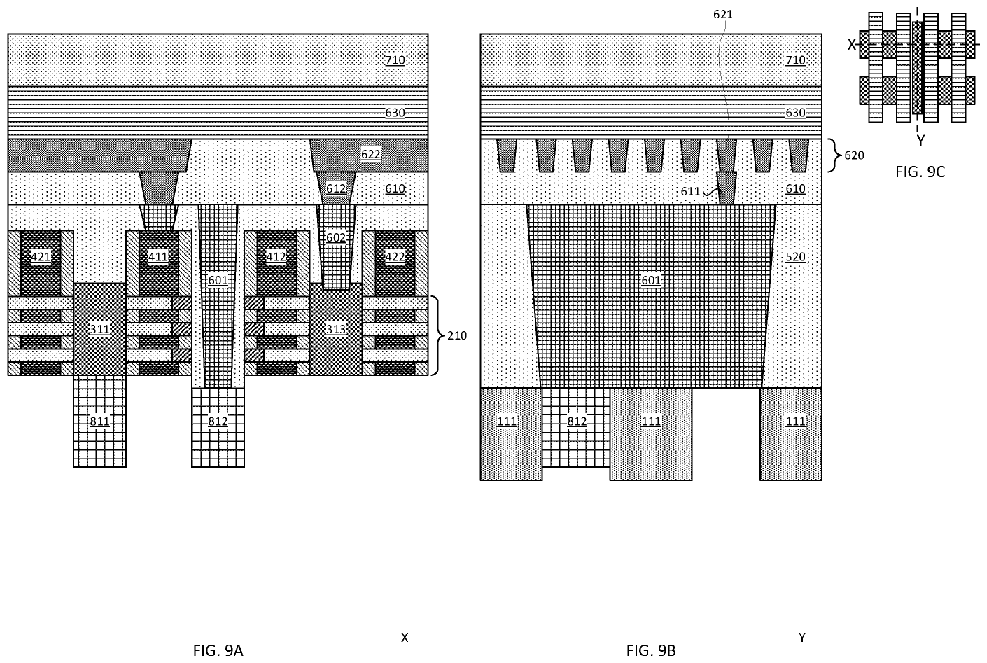

FIGS. 9A and 9B are demonstrative illustrations of different cross-sectional views and FIG. 9C is a simplified top view of a semiconductor structure in a step of manufacturing thereof, according to one embodiment of present invention. More particularly, following the step illustrated in FIGS. 8A, 8B, and 8C, embodiments of present invention provide continuing to remove the etch-stop layer 102 through a selective etch process to expose the Si layer 103, and selectively remove the Si layer 103 to expose the embedded STI 111, and the one or more placeholders such as the first and the second placeholder 811 and 812.

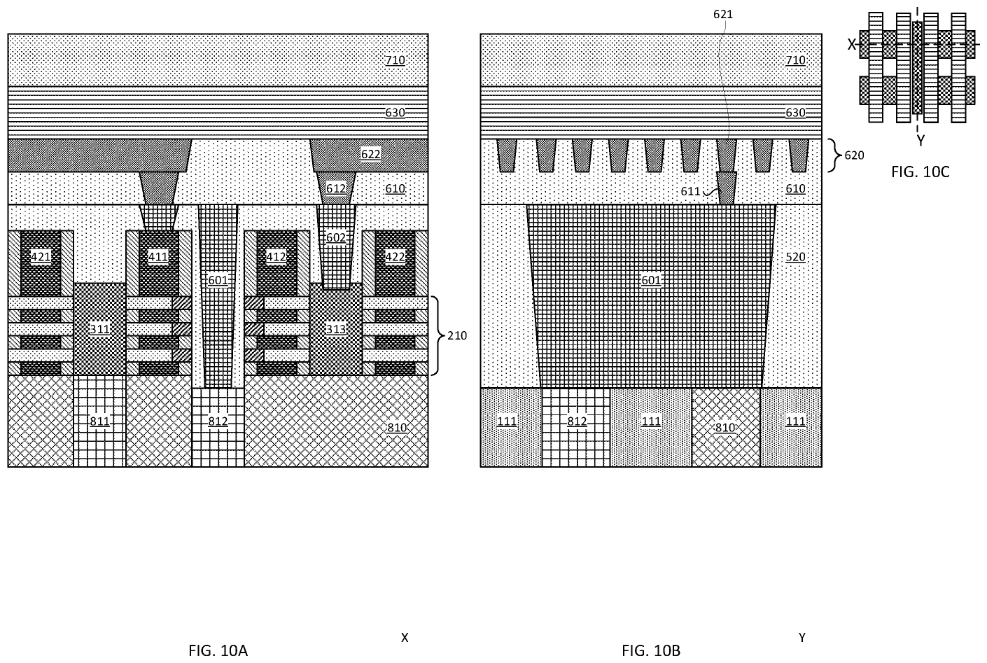

FIGS. 10A and 10B are demonstrative illustrations of different cross-sectional views and FIG. 10C is a simplified top view of a semiconductor structure in a step of manufacturing thereof, according to one embodiment of present invention. More particularly, following the step illustrated in FIGS. 9A, 9B, and 9C, embodiments of present invention provide depositing a dielectric material to form a dielectric layer 810 replacing the removed Si layer 103, and subsequently applying a CMP process to planarize a top surface of the dielectric layer 810 (note: the structure 10 is now being flipped upside-down for processing) until the first and the second placeholders 811 and 812 are exposed.

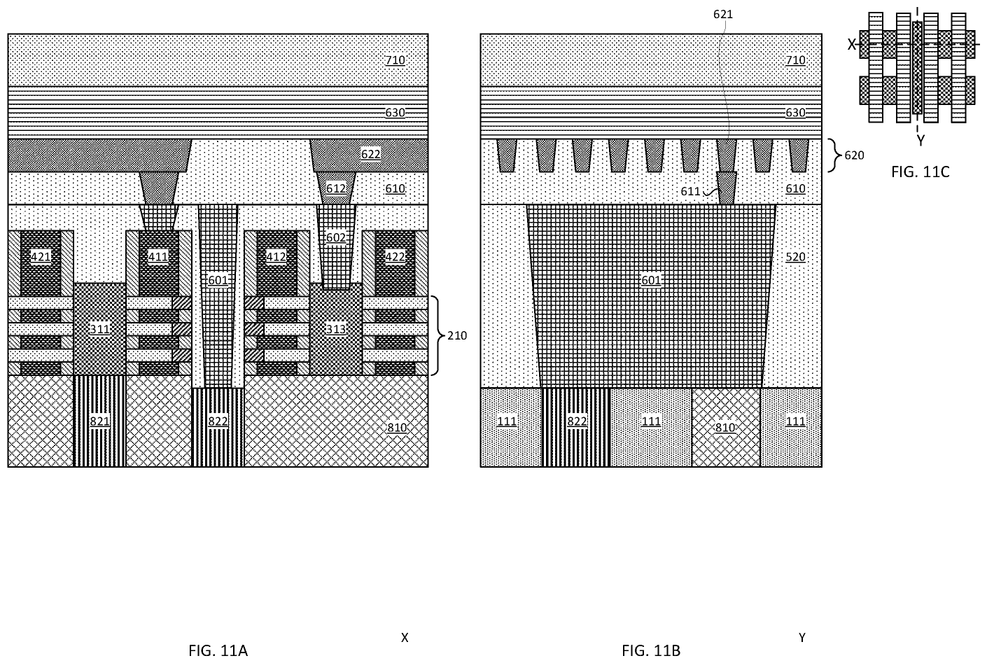

FIGS. 11A and 11B are demonstrative illustrations of different cross-sectional views and FIG. 11C is a simplified top view of a semiconductor structure in a step of manufacturing thereof, according to one embodiment of present invention. More particularly, following the step illustrated in FIGS. 10A, 10B, and 10C, embodiments of present invention provide removing the first and the second placeholder 811 and 812, in a selective etch process, to create openings exposing a bottom surface of the first S/D region 311 and a bottom surface of the deep trench via 601; filling the openings with conductive materials such as W, Co, Ru, Cu, Al or other suitable conductive material, together with possibly a silicide liner and/or metal adhesion liner, to form a backside S/D contact 821 and a backside contact 822.

Since the second placeholder 812 has a lower height than the first placeholder 811, a height of the backside contact 822 may be lower than a height of the backside S/D contact 821. The backside S/D contact 821 is formed in contact with a bottom surface of the first S/D region 311 from underneath thereof. The backside contact 822 is formed in contact with a bottom surface of the deep trench via 601 from underneath thereof as well.

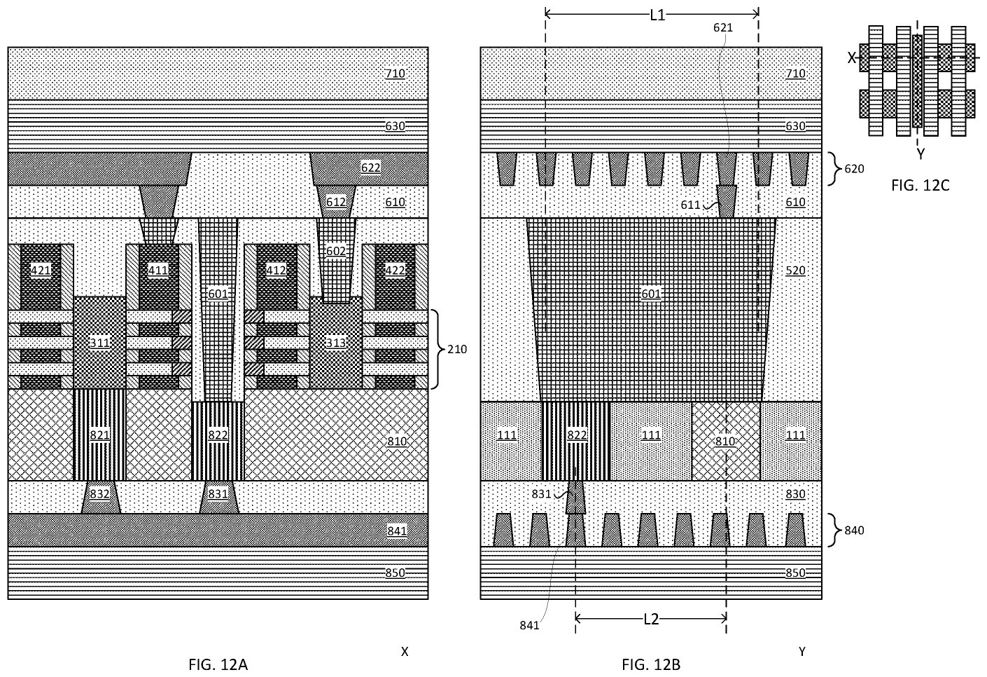

FIGS. 12A and 12B are demonstrative illustrations of different cross-sectional views and FIG. 12C is a simplified top view of a semiconductor structure in a step of manufacturing thereof, according to one embodiment of present invention. More particularly, following the step illustrated in FIGS. 11A, 11B, and 11C, embodiments of present invention provide forming a dielectric layer 830 on top of the backside S/D contact 821, the backside contact 822 and the dielectric layer 810; forming one or more backside vias such as a first backside via 831 and a second backside via 832. The first backside via 831 is in direct contact with the backside contact 822 and the second backside via 832 is in direct contact with the backside S/D contact 821.

Embodiments of present invention further provide forming a backside metal level such as a backside metal level 840 on top of the dielectric layer 830. The backside metal level 840 may include a plurality of metal tracks such as a plurality of metal wires, including a first backside metal wire 841, orientated in a second direction perpendicular or orthogonal to the length direction of the deep trench via 601. In other words, the first frontside metal wire 621 and the first backside metal wire 841 may be parallel to each other. In one embodiment, the first frontside metal wire 621 is not vertically aligned with the first backside metal wire 841, and a horizontal distance L2 between the first frontside metal wire 621 and the first backside metal wire 841 may be less than the length L1 of the deep trench via 601.

Embodiments of present invention further provide forming additional backside metal levels or backside BEOL structure 850 on top of the backside metal level 840, thereby forming the semiconductor structure 10.

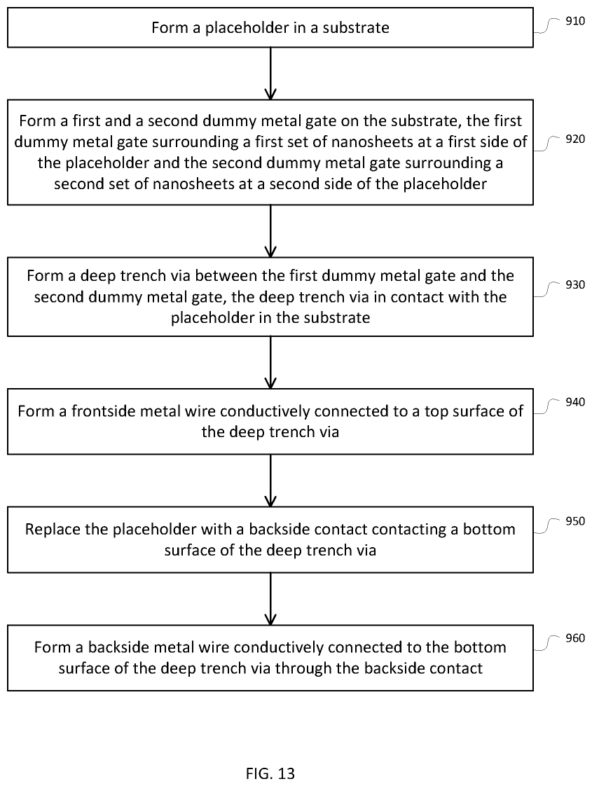

FIG. 13 is a demonstrative illustration of a flow-chart of a method of manufacturing a semiconductor structure according to embodiments of present invention. The method includes (910) forming a placeholder in a substrate; (920) forming a first and a second dummy metal gate on the substrate, the first dummy metal gate surrounding a first set of nanosheets at a first side of the placeholder and the second dummy metal gate surrounding a second set of nanosheets at a second side of the placeholder; (930) forming a deep trench via between the first dummy metal gate and the second dummy metal gate, the deep trench via in contact with the placeholder in the substrate; (940) forming a frontside metal wire conductively connected to a top surface of the deep trench via; (950) replacing the placeholder with a backside contact contacting a bottom surface of the deep trench via; and (960) forming a backside metal wire conductively connected to the bottom surface of the deep trench via through the backside contact.

Various examples may possibly be described by one or more of the following features in the following numbered clauses:
Clause 1: A semiconductor structure comprising: a deep trench via in a double diffusion region; a frontside metal wire conductively connected to a top surface of the deep trench via; and a backside metal wire conductively connected to a bottom surface of the deep trench via, wherein the frontside metal wire and the backside metal wire are parallel to each other and orthogonal to the deep trench via.
Clause 2: The semiconductor structure of clause 1, further comprising a first dummy metal gate and a second dummy metal gate, wherein the double diffusion region is between the first dummy metal gate and the second dummy metal gate and the top surface of the deep trench via is at or above a top surface of the first dummy metal gate and the second dummy metal gate.
Clause 3: The semiconductor structure of clause 2, further comprising a first set of nanosheets surrounded by the first dummy metal gate and a first set of inner spacers next to the first set of nanosheets, and a second set of nanosheets surrounded by the second dummy metal gate and a second set of inner spacers next to the second set of nanosheets, wherein the deep trench via is between the first set of inner spacers and the second set of inner spacers.
Clause 4: The semiconductor structure of clause 3, further comprising a first sidewall spacer at a sidewall of the first dummy metal gate and a second sidewall spacer at a sidewall of the second dummy metal gate, wherein the deep trench via is insulated from the first and the second dummy metal gate by the first and the second sidewall spacer and from the first and the second set of nanosheets by the first and the second set of inner spacers.
Clause 5: The semiconductor structure of clause 2, further comprising a first nanosheet transistor having a first source/drain (S/D) region adjacent to the first dummy metal gate, a second nanosheet transistor having a second S/D region adjacent to the second dummy metal gate, a backside contact contacting the deep trench via from underneath thereof, and a backside S/D contact contacting the first S/D region from underneath thereof, wherein a height of the backside contact is lower than a height of the backside S/D contact.
Clause 6: The semiconductor structure of clause 1, further comprising a frontside via, a backside via, and a backside contact, wherein the frontside metal wire is conductively connected to the top surface of the deep trench via through the frontside via, and the backside metal wire is conductively connected to the bottom surface of the deep trench via through the backside via and the backside contact.
Clause 7: The semiconductor structure of clause 1, wherein the frontside metal wire is not vertically aligned with the backside metal wire and a horizontal distance between the frontside and backside metal wires is less than a length of the deep trench via.
Clause 8: A method of forming a semiconductor structure comprising: forming a placeholder in a substrate; forming a first dummy metal gate and a second dummy metal gate on the substrate, the first dummy metal gate surrounding a first set of nanosheets at a first side of the placeholder and the second dummy metal gate surrounding a second set of nanosheets at a second side of the placeholder; forming a deep trench via between the first dummy metal gate and the second dummy metal gate, the deep trench via in contact with the placeholder in the substrate; forming a frontside metal wire conductively connected to a top surface of the deep trench via; replacing the placeholder with a backside contact contacting a bottom surface of the deep trench via; and forming a backside metal wire conductively connected to the bottom surface of the deep trench via through the backside contact.
Clause 9: The method of clause 8, further comprising forming a frontside via directly contacting the top surface of the deep trench via, wherein the frontside metal wire directly contacts the frontside via.
Clause 10: The method of clause 8, further comprising forming a backside via directly contacting the backside contact, wherein the backside metal wire directly contacts the backside via.
Clause 11: The method of clause 8, further comprising forming a first set of inner spacers next to an end of the first set of nanosheets facing the deep trench via and a second set of inner spacers next to an end of the second set of nanosheets facing the deep trench via such that the deep trench via is between the first set of inner spacers and the second set of inner spacers.
Clause 12: The method of clause 8, wherein forming the deep trench via comprising creating a deep trench via opening in a dielectric layer between the first dummy metal gate and the second dummy metal gate; and filling the deep trench via opening with a conductive material to form the deep trench via, wherein a top surface of the deep trench via is at a level at or above a top surface of the first and the second dummy metal gate.
Clause 13: The method of clause 8, wherein forming the frontside metal wire comprises forming the frontside metal wire in a first direction orthogonal to the deep trench via; and wherein forming the backside metal wire comprises forming the backside metal wire in a second direction orthogonal to the deep trench via and parallel to the first direction, wherein the backside metal wire is not vertically aligned with the frontside metal wire.
Clause 14: The method of clause 8, wherein replacing the placeholder with the backside contact comprises selectively removing the placeholder from a backside of the substrate to creating an opening exposing the bottom surface of the deep trench via and filling the opening with a conductive material to form the backside contact.
Clause 15: The method of clause 8, wherein forming the first and the second dummy metal gate comprises forming a set of metal gates that includes a first metal gate of a first transistor, a second metal gate of a second transistor, and the first and the second dummy metal gate; and wherein replacing the placeholder with the backside contact further comprises forming a backside source/drain (S/D) contact underneath a first S/D region of the first transistor, wherein a height of the backside contact is lower than a height of the backside S/D contact.
Clause 16: A semiconductor structure comprising: a deep trench via in a double diffusion region between a first dummy metal gate and a second dummy metal gate; a frontside metal wire conductively connected to a top surface of the deep trench via through a frontside via; and a backside metal wire conductively connected to a bottom surface of the deep trench via through a backside via and a backside contact, wherein the frontside metal wire and the backside metal wire are not vertically aligned but parallel to each other, and a first direction of the frontside metal wire and a second direction of the backside metal wire are orthogonal to a length direction of the deep trench via.
Clause 17: The semiconductor structure of clause 16, wherein the top surface of the deep trench via is at or above a top surface of the first dummy metal gate and the second dummy metal gate.
Clause 18: The semiconductor structure of clause 17, further comprising a first set of nanosheets surrounded by the first dummy metal gate and a first set of inner spacers next to the first set of nanosheets, and a second set of nanosheets surrounded by the second dummy metal gate and a second set of inner spacers next to the second set of nanosheets, wherein the deep trench via is between the first set of inner spacers and the second set of inner spacers.
Clause 19: The semiconductor structure of clause 18, further comprising a first sidewall spacer at a sidewall of the first dummy metal gate and a second sidewall spacer at a sidewall of the second dummy metal gate, wherein the deep trench via is insulated from the first and the second dummy metal gate by the first and the second sidewall spacer and insulated from the first and the second set of nanosheets by the first and the second set of inner spacers.
Clause 20: The semiconductor structure of clause 16, wherein a horizontal distance between the frontside metal wire and the backside metal wire is less than the length of the deep trench via.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a deep trench via in a double diffusion region;
a frontside metal wire conductively connected to a top surface of the deep trench via; and
a backside metal wire conductively connected to a bottom surface of the deep trench via,
wherein the frontside metal wire and the backside metal wire are parallel to each other and orthogonal to the deep trench via.

2. The semiconductor structure of claim 1, further comprising a first dummy metal gate and a second dummy metal gate, wherein the double diffusion region is between the first dummy metal gate and the second dummy metal gate and the top surface of the deep trench via is at or above a top surface of the first dummy metal gate and the second dummy metal gate.

3. The semiconductor structure of claim 2, further comprising a first set of nanosheets surrounded by the first dummy metal gate and a first set of inner spacers next to the first set of nanosheets, and a second set of nanosheets surrounded by the second dummy metal gate and a second set of inner spacers next to the second set of nanosheets, wherein the deep trench via is between the first set of inner spacers and the second set of inner spacers.

4. The semiconductor structure of claim 3, further comprising a first sidewall spacer at a sidewall of the first dummy metal gate and a second sidewall spacer at a sidewall of the second dummy metal gate, wherein the deep trench via is insulated from the first and the second dummy metal gate by the first and the second sidewall spacer and from the first and the second set of nanosheets by the first and the second set of inner spacers.

5. The semiconductor structure of claim 2, further comprising a first nanosheet transistor having a first source/drain (S/D) region adjacent to the first dummy metal gate, a second nanosheet transistor having a second S/D region adjacent to the second dummy metal gate, a backside contact contacting the deep trench via from underneath thereof, and a backside S/D contact contacting the first S/D region from underneath thereof, wherein a height of the backside contact is lower than a height of the backside S/D contact.

6. The semiconductor structure of claim 1, further comprising a frontside via, a backside via, and a backside contact, wherein the frontside metal wire is conductively connected to the top surface of the deep trench via through the frontside via, and the backside metal wire is conductively connected to the bottom surface of the deep trench via through the backside via and the backside contact.

7. The semiconductor structure of claim 1, wherein the frontside metal wire is not vertically aligned with the backside metal wire and a horizontal distance between the frontside and backside metal wires is less than a length of the deep trench via.

8. A method of forming a semiconductor structure comprising:
forming a placeholder in a substrate;
forming a first dummy metal gate and a second dummy metal gate on the substrate, the first dummy metal gate surrounding a first set of nanosheets at a first side of the placeholder and the second dummy metal gate surrounding a second set of nanosheets at a second side of the placeholder;
forming a deep trench via between the first dummy metal gate and the second dummy metal gate, the deep trench via in contact with the placeholder in the substrate;
forming a frontside metal wire conductively connected to a top surface of the deep trench via;
replacing the placeholder with a backside contact contacting a bottom surface of the deep trench via; and
forming a backside metal wire conductively connected to the bottom surface of the deep trench via through the backside contact.

9. The method of claim 8, further comprising forming a frontside via directly contacting the top surface of the deep trench via, wherein the frontside metal wire directly contacts the frontside via.

10. The method of claim 8, further comprising forming a backside via directly contacting the backside contact, wherein the backside metal wire directly contacts the backside via.

11. The method of claim 8, further comprising forming a first set of inner spacers next to an end of the first set of nanosheets facing the deep trench via and a second set of inner spacers next to an end of the second set of nanosheets facing the deep trench via such that the deep trench via is between the first set of inner spacers and the second set of inner spacers.

12. The method of claim 8, wherein forming the deep trench via comprising creating a deep trench via opening in a dielectric layer between the first dummy metal gate and the second dummy metal gate; and filling the deep trench via opening with a conductive material to form the deep trench via, wherein a top surface of the deep trench via is at a level at or above a top surface of the first and the second dummy metal gate.

13. The method of claim 8, wherein forming the frontside metal wire comprises forming the frontside metal wire in a first direction orthogonal to the deep trench via; and wherein forming the backside metal wire comprises forming the backside metal wire in a second direction orthogonal to the deep trench via and parallel to the first direction, wherein the backside metal wire is not vertically aligned with the frontside metal wire.

14. The method of claim 8, wherein replacing the placeholder with the backside contact comprises selectively removing the placeholder from a backside of the substrate to creating an opening exposing the bottom surface of the deep trench via and filling the opening with a conductive material to form the backside contact.

15. The method of claim 8, wherein forming the first and the second dummy metal gate comprises forming a set of metal gates that includes a first metal gate of a first transistor, a second metal gate of a second transistor, and the first and the second dummy metal gate; and wherein replacing the placeholder with the backside contact further comprises forming a backside source/drain (S/D) contact underneath a first S/D region of the first transistor, wherein a height of the backside contact is lower than a height of the backside S/D contact.

16. A semiconductor structure comprising:
a deep trench via in a double diffusion region between a first dummy metal gate and a second dummy metal gate;
a frontside metal wire conductively connected to a top surface of the deep trench via through a frontside via; and
a backside metal wire conductively connected to a bottom surface of the deep trench via through a backside via and a backside contact,
wherein the frontside metal wire and the backside metal wire are not vertically aligned but parallel to each other, and a first direction of the frontside metal wire and a second direction of the backside metal wire are orthogonal to a length direction of the deep trench via.

17. The semiconductor structure of claim 16, wherein the top surface of the deep trench via is at or above a top surface of the first dummy metal gate and the second dummy metal gate.

18. The semiconductor structure of claim 17, further comprising a first set of nanosheets surrounded by the first dummy metal gate and a first set of inner spacers next to the first set of nanosheets, and a second set of nanosheets surrounded by the second dummy metal gate and a second set of inner spacers next to the second set of nanosheets, wherein the deep trench via is between the first set of inner spacers and the second set of inner spacers.

19. The semiconductor structure of claim 18, further comprising a first sidewall spacer at a sidewall of the first dummy metal gate and a second sidewall spacer at a sidewall of the second dummy metal gate, wherein the deep trench via is insulated from the first and the second dummy metal gate by the first and the second sidewall spacer and insulated from the first and the second set of nanosheets by the first and the second set of inner spacers.

20. The semiconductor structure of claim 16, wherein a horizontal distance between the frontside metal wire and the backside metal wire is less than the length of the deep trench via.
